(19) United States
(12) Patent Application Publication
(10) Pub. No.: US 2012/0048199 A1
(43) Pub. Date: Mar. 1, 2012

(54) CRUCIBLE AND EVAPORATION DEPOSITION DEVICE HAVING SAME

(75) Inventor: SHAO-KAI PEI, Tu-Cheng (TW)

(73) Assignee: HON HAI PRECISION INDUSTRY CO., LTD., Tu-Cheng (TW)

(21) Appl. No.: 12/963,819

(22) Filed: Dec. 9, 2010

(30) Foreign Application Priority Data
Aug. 24, 2010 (TW) 99128168

(51) Int. Cl. C23C 16/455; B05C 11/10

(52) U.S. Cl. 118/726; 118/600

(57) ABSTRACT

A crucible includes a body, an ejector and a drive member. The body has a receptacle for receiving coating material, and a bottom in the receptacle. The bottom has an ejector hole communicating with the receptacle. The ejector is positioned below the receptacle and received in the ejector hole. The drive member has a drive shaft coupled to the ejector. The drive member is configured for driving the ejector to move toward or away from the receptacle along a central axis of the ejector hole so that the coating material can be moved up or down in the receptacle.

### BACKGROUND

1. Technical Field

The present disclosure relates to a crucible and a related evaporation deposition device.

2. Description of Related Art

Evaporation deposition devices typically include a deposition chamber, a crucible, and a carrier positioned in the deposition chamber. The crucible contains coating material, and the carrier supports workpieces near the crucible. During the coating process, the coating material will be gradually depleted and may not work as well even if only partially depleted. Therefore, in order to continue coating, coating material must be manually added into the crucible.

However, manually adding coating material to the crucible is inefficient and may cause the coating materials to become polluted.

Therefore, a crucible which can overcome the above-mentioned problems is desired.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is an isometric view of a crucible according to a first embodiment.

FIG. 2 is an exploded, isometric view of the crucible of FIG. 1.

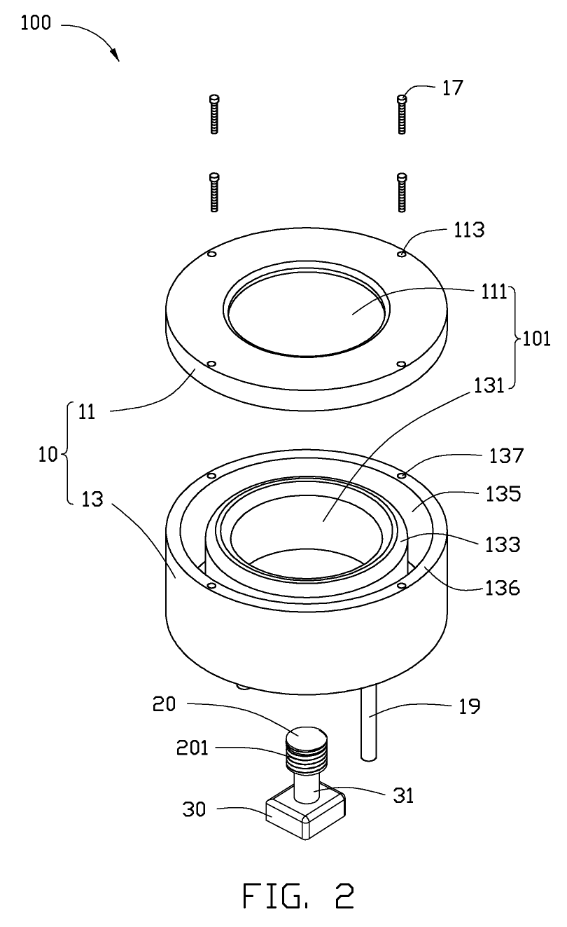

FIG. 3 is a cutaway view of the crucible of FIG. 1.

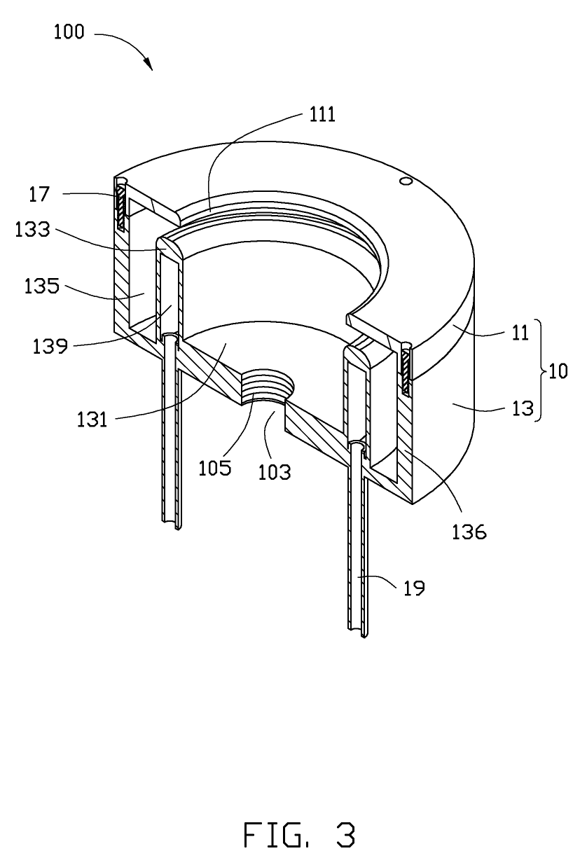

FIG. 4 is an isometric view of the crucible of FIG. 1 containing a cylindrical coating material.

FIG. 5 is a sectional view of an evaporation deposition device according to one exemplary embodiment.

### DETAILED DESCRIPTION

Embodiments will now be described in detail below with reference to the drawings.

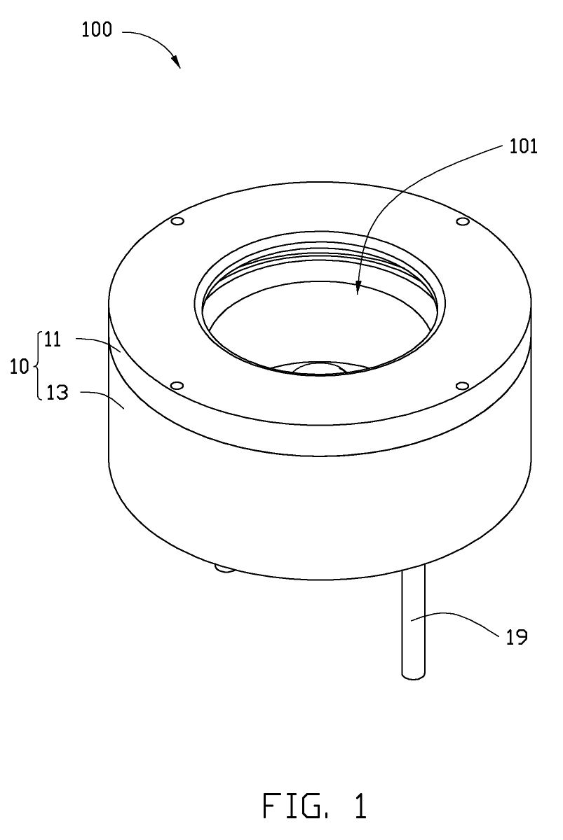

Referring to FIG. 1, a crucible 100 for containing coating material in accordance with a first embodiment is provided. The crucible 100 includes a body 10, an ejector 20, and a drive member 30.

The body 10 has a receptacle 101 for receiving coating material, and an ejector hole 103 at the bottom of the body 10. The ejector hole 103 communicates with the receptacle 101. In this embodiment, the body 10 includes a ring-shaped cover 11, and a cylindrical base 13. The cover 11 defines a first through hole 111 in the central area. The base 13 has a central hole 131 located in the central area, an inner wall 133 surrounding the central hole 131, a ring-shaped trough 135 surrounding the inner wall 133, and an outer wall 136 surrounding the ring-shaped trough 135. The cover 11 and the base 13 cooperatively form the body 10. The first through hole 111 and the central hole 131 cooperatively form the receptacle 101. The ring-shaped trough 135 and the receptacle 101 communicate with each other, and are separated by the inner wall 133. The ring-shaped trough 135 is between the inner wall 133 and the outer wall 136. The ring-shaped trough 135 can be full of air. Therefore, when the crucible 10 is heated, the coating material received in the receptacle 101 can be evenly heated. The ejector hole 103 is below the central hole 131.

In this embodiment, the first through hole 111, the central hole 131, the receptacle 101 and the ejector hole 103 are all cylindrical and coaxial. In alternative embodiments, the first through hole 111, the central hole 131, the receptacle 101 and the ejector hole 103 may all be cubic.

In this embodiment, four first screw holes 113 are defined in the periphery of the cover 11. The base 13 has four second screw holes 137 located in the outer wall 136 corresponding to the first screw holes 113. The four first screw holes 113 and the four second screw holes 137 are for engaging with four respective screws 17.

In this embodiment, both of the cover 11 and the base 13 are made of copper, tantalum, molybdenum, tungsten, or other thermally conductive metal or their alloys.

The base 13 further has a ring channel 139. The ring channel 139 is located inside the inner wall 133, and surrounds the central hole 131. The ring channel 139 communicates with a cooling pipe 19 outside the crucible 10. Therefore, to cool the crucible 10, cooling fluid, such as water, can run through the ring channel 139, and cool the crucible 10.

The ejector 20 is positioned below the receptacle 101, and received in the ejector hole 103. The ejector 20 is capable of rotating or moving in the ejector hole 103. Accordingly, the ejector 20 can move upward or downward along a central axis of the ejector hole 103. In this embodiment, the ejector 20 is cylindrical, and coaxial to the ejector hole 103.

In this embodiment, the inner surface of the ejector hole 103 has an inner screw thread 105 defined thereon. The outer surface of the ejector has an outer screw thread 201 defined thereon. The outer screw thread 201 engages with the inner screw thread 105. Therefore, the ejector 20 is capable of being screwed into the receptacle 101.

The drive member 30 is coupled to the ejector 20. The drive member 30 is configured for driving the ejector 20 to move toward or away from the receptacle 101 along a central axis of the ejector hole 103, so that the coating material can be moved up or down in the receptacle 101. In this embodiment, the drive member 30 is a motor with a driving shaft 31. The diameter of the driving shaft 31 is less than the diameter of the ejector hole 103. The driving shaft 31 is coupled to the ejector 20. The driving shaft 31 and the ejector 20 are coaxial to each other. Therefore, the drive member 30 can drive the ejector 20 to screw into or out of the receptacle 101.

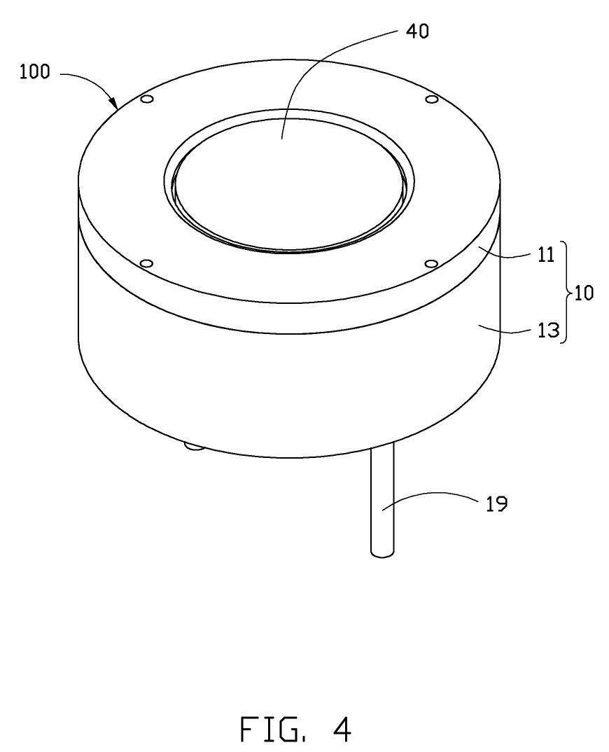

Referring to FIG. 4, in operation, a cylindrical coating material 40 is placed in the receptacle 101 (not labeled in FIG. 4) of the crucible 100. The crucible 100 is positioned in the evaporation deposition system (not shown in FIG. 4). In the coating process, the coating material 40 is heated by high-energy electron beams, and vaporizes to deposit onto workpieces. After a period of time, some of the coating material 40 is depleted, and accordingly, a thickness of the coating material 40 decreases. Accordingly, different size holes form in the coating material 40 and the top surface of the material 40 lowers relative to the cover 11. As a result of depletion, the top surface of the coating material 40 may not be totally exposed to be heated. In order to keep a stable evaporation rate during the next coating process, the top surface of the coating material 40 should be smoothed out and totally exposed. After a tool is applied to flatten the surface of the coating material 40, the drive member 30 is activated to drive the ejector 20 to move upwards along the central axis of the ejector hole 103, and then the top surface of the coating material 40 is lifted up by the ejector 20. Therefore, the top surface of the coating material 40 can be totally exposed to be heated, and it's not necessary to add coating material into the receptacle 101 until it is totally depleted.

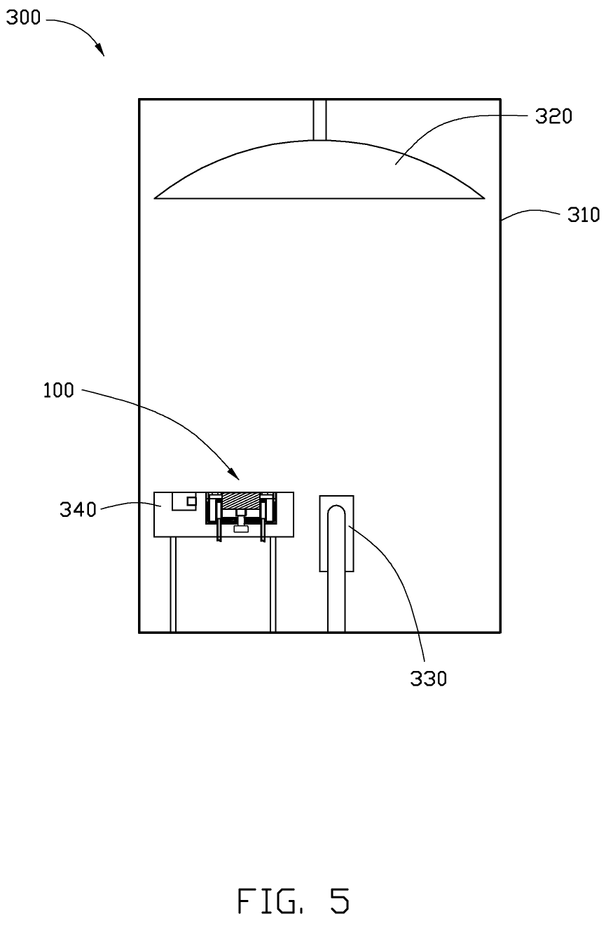

Referring to FIG. 5, an evaporation deposition device 300 in accordance with an alternative embodiment is provided. The evaporation deposition device 300 includes a deposition chamber 310, a carrier 320, a plasma source 330, a heating system 340, and a crucible 100.

The deposition chamber 310 is a vacuum chamber. The carrier 320, the plasma source 330, the heating system 340, and the crucible 100 are all located in the deposition chamber 310.

The carrier 320 supports workpieces, and keeps the workpieces aligned with the crucible 100. The plasma source 330 forms plasma in the deposition chamber 310. In this embodiment, the heating system 340 is an electron gun, used to form high-energy electron beams to heat and vaporize the cylindrical coating material 40 (no labeled in the FIG. 5). Finally, the resultant material is deposited onto the workpieces.

In this embodiment, the carrier 320 is on the top of the deposition chamber 310, and above the crucible 100. The plasma source 330 and the crucible 100 are below the carrier 320. The heating system 340 is beside the crucible 100.

Due to the crucible 100 including the drive member 30, the cylindrical coating material 40 received in the receptacle 101 of the crucible 100 can be moved up or down automatically. Thus, in the coating process, the top surface of the coating material 40 can be totally exposed to be heated even when partially depleted. Therefore, it's not necessary to manually add coating material into the crucible 100 at intervals, and processing coating material is more efficient. Additionally, the crucible 100 can greatly reduce the possibility of the coating material being polluted during manual repletion.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A crucible, comprising:
a body having a receptacle for receiving coating material therein, and a bottom in the receptacle, the bottom having an ejector hole communicating with the receptacle;
an ejector positioned below the receptacle and received in the ejector hole; and
a drive member comprising a drive shaft coupled to the ejector, the drive member being configured for driving the ejector to move toward or away from the receptacle along a central axis of the ejector hole so that the coating material can be moved up or down in the receptacle.

2. The crucible of claim 1, wherein the body comprises a ring-shaped cover and a cylindrical base, the cover has a first through hole defined in a central area thereof, the base has a central hole located in a central area thereof, an inner wall surrounding the central hole, a ring-shaped trough surrounding the ring wall, and an outer wall surrounding the ring-shaped trough, the first through hole and the central hole cooperatively form the receptacle, and the ring-shaped trough and the receptacle communicate with each other.

3. The crucible of claim 2, wherein the first through hole, the central hole, the receptacle and the ejector hole are cylindrical and coaxial.

4. The crucible of claim 3, wherein the ejector is threadedly engaged in the ejector hole.

5. The crucible of claim 3, wherein the ejector is cylindrical and coaxial with the drive shaft.

6. The crucible of claim 2, further comprising a ring channel inside the inner wall, for communicating with a cooling pipe outside the crucible.

7. The crucible of claim 2, wherein both the cover and the base are made of thermally conductive metal.

8. An evaporation deposition device, comprising:
a deposition chamber; and
a crucible arranged in the deposition chamber, the crucible comprising:
a body having a receptacle for receiving coating material therein, and a bottom in the receptacle, the bottom having an ejector hole communicating with the receptacle;
an ejector positioned below the receptacle and received in the ejector hole; and
a drive member comprising a drive shaft coupled to the ejector, the drive member being configured for driving the ejector to move toward or away from the receptacle along a central axis of the ejector hole so that the coating material can be moved up or down in the receptacle.

9. The evaporation deposition device of claim 9, wherein the body comprises a ring-shaped cover and a cylindrical base, the cover has a first through hole defined in a central area thereof, the base has a central hole located in a central area thereof, an inner wall surrounding the central hole, a ring-shaped trough surrounding the ring wall, and an outer wall surrounding the ring-shaped trough, the first through hole and the central hole cooperatively form the receptacle, and the ring-shaped trough and the receptacle communicate with each other.

10. The evaporation deposition device of claim 9, wherein the first through hole, the central hole, the receptacle and the ejector hole are cylindrical and coaxial.

11. The evaporation deposition device of claim 10, wherein the ejector is threadedly engaged in the ejector hole.

12. The evaporation deposition device of claim 10, wherein the ejector is cylindrical and coaxial with the drive shaft.

13. The evaporation deposition device of claim 9, further comprising a ring channel inside the inner wall, for communicating with a cooling pipe outside the crucible.

14. The evaporation deposition device of claim 9, wherein both the cover and the base are made of thermally conductive metal.

15. A crucible comprising:
a body having a ring-shaped cover, a bottom wall, a cylindrical inner wall and a cylindrical outer wall surrounding the inner wall, the bottom wall defining an ejector hole therein, the inner wall and the outer wall extending from the bottom wall and cooperatively forming a ring-shaped trough therebetween, the inner wall and the bottom cooperatively defining a cylindrical receiving space for receiving coating material, the receiving space being in communication with the trough, the cover mounted to the outer wall and spaced from the inner wall, the cover substantially covering the ring-shaped trough; and
an ejector engaged in the ejector hole, the ejector movable in the ejector hole toward or away from the cover.
